(19) United States
(12) Patent Application Publication
(10) Pub. No.: US 2024/0332194 A1
(43) Pub. Date: Oct. 3, 2024

(54) CHIP MODULE ASSEMBLY

(71) Applicant: International Business Machines Corporation, Armonk, NY (US)

(72) Inventors: Mukta Ghate Farooq, Hopewell Junction, NY (US); FEE LI LIE, Albany, NY (US)

(21) Appl. No.: 18/128,758

(22) Filed: Mar. 30, 2023

(51) Int. Cl. H01L 23/538; H01L 23/00; H01L 23/31; H01L 23/528; H01L 25/065

(52) U.S. Cl. CPC H01L 23/5384; H01L 23/3157; H01L 23/528; H01L 24/05; H01L 24/08; H01L 24/16; H01L 24/32; H01L 24/73; H01L 25/0652; H01L 2224/05147; H01L 2224/08145; H01L 2224/16227; H01L 2224/32225; H01L 2224/73204; H01L 2924/1431; H01L 2924/1434; H01L 2924/182; H10B 80/00

(57) ABSTRACT

An electronic device including a chip module assembly is provided. The chip module assembly includes at least one first semiconductor chip pair located at a first chip level, a bridge die interconnecting the at least one first semiconductor chip pair, and at least one second semiconductor chip pair located on top of the first chip level, wherein the at least one second chip pair are connected to each other through the at least one first semiconductor chip pair and the bridge die.

The present application relates to semiconductor technology, and more particularly to an electronic device that includes a chip module assembly.

In a typical multi-chip integrated circuit, interposers may be used to electrically connect the semiconductor chips to a substrate. In other words, the semiconductor chips can communicate with one another via the substrate. However, the bandwidth of the substrate is limited. Therefore, there is a need for a structure (and a method for forming the same) in which more communication channels between the semiconductor chips are provided.

### SUMMARY

An electronic device is provided that includes a chip module assembly. The chip module assembly permits connection between two of more stacked semiconductor chips through first level semiconductor chips and one or more bridge dies that are joined on top of the first level semiconductor chips.

In one aspect of the present application, an electronic device is provided. In one embodiment, the electronic device includes a chip module assembly attached to a laminate. The chip module assembly includes at least one first semiconductor chip pair located at a first chip level, a bridge die interconnecting the at least one first semiconductor chip pair, and at least one second semiconductor chip pair located on top of the first chip level, wherein the at least one second chip pair are connected to each other through the at least one first semiconductor chip pair and the bridge die.

### BRIEF DESCRIPTION OF THE DRAWINGS

FIG. 1 is a cross sectional view of an exemplary structure that can be employed in an embodiment of the present application, the exemplary structure including at least one bridge die embedded in a first fixture.

FIG. 2 is a cross sectional view of the exemplary structure shown in FIG. 1 after forming a plurality of first semiconductor chips including at least one first semiconductor chip pair on a surface of the first fixture, wherein each first semiconductor chip pair of the plurality of first semiconductor chips is connected to one of the bridge dies.

FIG. 3 is a cross sectional view of the exemplary structure shown in FIG. 2 after forming a first gap fill material between each first semiconductor chip pair.

FIG. 4 is a cross sectional view of the exemplary structure shown in FIG. 3 after removing one of the first semiconductor chip pairs from the first fixture, placing the removed first semiconductor chip pair upside down in a second fixture, forming a plurality of second semiconductor chips including at least one second semiconductor pair on a surface of each first semiconductor chip pair, wherein each second semiconductor chip pair of the plurality of second semiconductor chips is connected to one of the bridge dies, and forming a second gap fill material between each second semiconductor chip pair to provide a chip module assembly.

FIG. 5 is cross sectional view of the exemplary structure of FIG. 4 after removing the chip module assembly from the second fixture and placing the removed chip module assembly upside down in a third fixture.

FIG. 6 is a cross sectional view of the exemplary structure shown in FIG. 5 after forming or depositing a plurality of solder balls on a physically exposed surface of the first semiconductor chip pair of the chip module assembly.

FIG. 7 is a cross sectional view of the exemplary structure of FIG. 6 after bonding the chip module assembly to a laminate to provide an electronic device in accordance with an embodiment of the present application.

FIG. 8 is a cross sectional view of another electronic device in accordance with another embodiment of the present application which can be derived from the processing illustrated in FIGS. 1-7.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

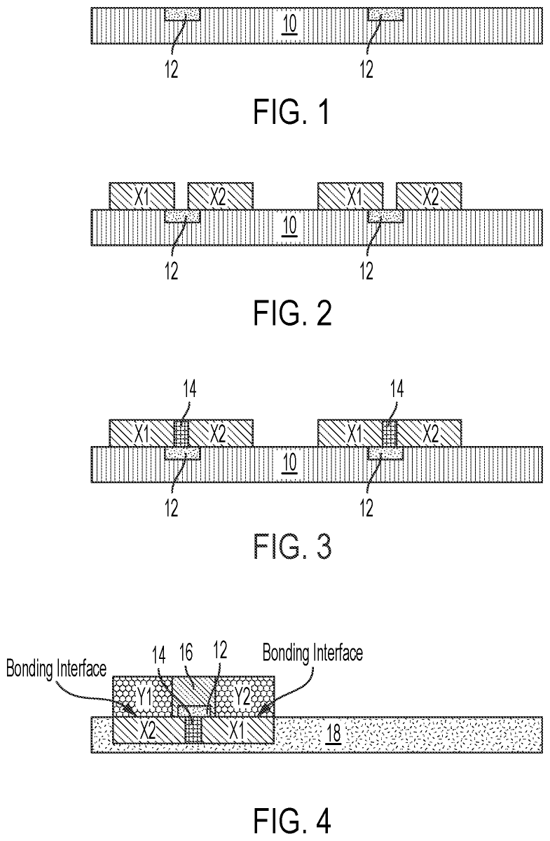

Reference is first made to FIG. 1, which illustrates an exemplary structure that can be employed in an embodiment of the present application. The exemplary structure illustrated in FIG. 1 includes at least one bridge die 12 (two of which are shown by way of one example) embedded in a first fixture 10. Notably, each bridge die 12 is located in a recessed region that is present in the first fixture 10.

The first fixture 10 can be composed of well-known materials. In some embodiments, the first fixture 10 is composed of a semiconductor material having semiconducting properties. In one example, the first fixture 10 is composed of silicon or a silicon germanium alloy. In other embodiments, the first fixture 10 can be composed of a dielectric material such as, for example, silicon dioxide, silicon nitride or silicon oxynitride. In yet other embodiments, the first fixture 10 can be composed of a metal such as, for example, copper or aluminum. Embodiments are contemplated in which the first fixture 10 includes a multilayered stack. The multilayered stack that can provide the first fixture 10 can include any combination of semiconductor materials, dielectric materials and/or metals. In one example, a multilayered stack of silicon and silicon dioxide can be used as the first fixture 10. In other embodiments, the first fixture 10 is composed of a plastic or ceramic.

Each bridge die 12 that is embedded in the first fixture 10 includes a semiconductor material, such as, for example, silicon, which contains wiring structures (metal via and/or metal lines) embedded therein. The wiring structures are composed of an electrically conductive metal or an electrically conductive metal alloy. Exemplary electrically conductive materials (i.e., metals or metal alloys) that can be use as the wiring structures include, but are not limited, copper (Cu), aluminum (Al), tungsten (W), cobalt (Co), ruthenium (Ru), rhodium (Rh), platinum (Pt) and alloys of Cu—Al. Each bridge die 12 can be rectangular in shape and can have a dimension of 1 mm to 5 mm by 1 mm to 5 mm.

In some embodiments, a diffusion barrier liner can be formed along a sidewall and bottom wall of the wiring structures. Exemplary diffusion barrier materials include, but are not limited to, titanium (It), tantalum (Ta), titanium nitride (TiN), tantalum nitride (TaN), tungsten nitride (WN), tungsten carbide (WC), an alloy thereof, or a stack thereof such as Ti/TiN and Ti/WC.

The wiring structures that are present in each bridge die 12 can be formed utilizing well-known metallization processes. The metallization process can include forming openings (lines and/or vias) in the semiconductor material and thereafter filling the openings with one of the above mentioned electrically conductive metals or electrically conductive metal alloys. The filling can include any suitable deposition process such as, for example, chemical vapor deposition (CVD), plasma enhanced chemical vapor deposition (PECVD), atomic layer deposition (ALD), or sputtering. A planarization process such as, for example, chemical mechanical polishing (CMP) can be performed after deposition of the electrically conductive material. In case in which a diffusion barrier liner is present, the metallization process mentioned above includes a step of forming a diffusion barrier material layer prior to filling the openings with an electrically conductive material. At least one of the wiring structures that is present in the semiconductor material that provides the bridge die 12 extends from a topmost surface of the semiconductor material to a bottommost surface of the semiconductor material. The wiring structure that extend from a topmost surface to a bottommost surface of the bridge die 12 can be referred to herein as through silicon via (TSV) structure.

The exemplary structure shown in FIG. 1 can be formed by forming at least one recessed region (i.e., opening) in the first fixture 10. The at one recessed region is designed to house one of the bridge die 12. The at least one recessed region can be formed by known techniques. In one example, the recessed region can be formed by lithography and etching. After forming the at least one recessed region, one bridge die 12 is placed into the recessed region by hand or mechanical means (e.g., a robot arm).

Referring now to FIG. 2, there is illustrated the exemplary structure shown in FIG. 1 after forming a plurality of first semiconductor chips including at least one first semiconductor chip pair X1-X2 on a surface the first fixture 10, wherein each first semiconductor chip pair X1-X2 of the plurality of first semiconductor chips is connected to one of the bridge dies 12. As is illustrated, a gap is present between the first semiconductor chips that provide each first semiconductor chip pair X1-X2. This gap lies above a portion of the bridge die 12. As is further illustrated, a first portion of the first semiconductor chips that provide each first semiconductor chip pair X1-X2 is located directly on a surface of one of the bridge die 12 and a second portion of the first semiconductor chips that provide each first semiconductor chip pair X1-X2 is located directly on a surface of the first fixture 10.

Each first semiconductor chip that provides the first semiconductor chip pairs X1-X2 has a first size and a first thickness. In one example, the first size of each first semiconductor chip that provides each first semiconductor chip pair X1-X2 is from 15 nm to 20 mm, and the first thickness for each first semiconductor chip that provides each first semiconductor chip pair X1-X2 is from 50 μm to 100 μm.

Each first semiconductor chips that provides the first semiconductor chip pairs X1-X2 includes a front-end-of-the line (FEOL) level that contains one or more semiconductor devices such as, for example, transistors located on a frontside of a wafer, a middle-of-the-line (MOL) level that includes a MOL dielectric containing a plurality of frontside contact structures embedded therein, and a back-end-of-the-line (BEOL) level that includes one or more interconnect dielectric layers having electrically conductive wiring structures embedded therein. Each first semiconductor chip that provides the first semiconductor chip pairs X1-X2 can also include backside power rails and a backside power distribution network located on a backside of the wafer. The backside of the wafer is further from the MOL or BEOL than is the frontside of the wafer. Each first semiconductor chip that provides the first semiconductor chip pairs X1-X2 that can be employed in the present application can be formed utilizing FEOL, MOL, BEOL, and backside wafer processing techniques that are well-known to those skilled in the art. At least one of the first semiconductor chips that provide the first semiconductor chip pairs X1-X2 includes a through silicon via, TSV, structure. The TSV structure present in at least one of the first semiconductor chips extends entirely throughout the chip so as to permit electrical contact with semiconductor chips that are formed thereon.

Each first semiconductor chip that provides the first semiconductor chip pairs X1-X2 includes metal bond pads (not specifically shown). The metal bond pads are formed on the uppermost surface and/or bottommost surface of each first semiconductor chip that provides the first semiconductor chip pairs X1-X2. The metal bond pads are composed of copper or any other like metal bond pad material. The metal bond pads can be formed utilizing techniques that are well-known in the art. The metal bond pads can be formed, for example, by deposition (CVD, PECVD, ALD, plating, sputtering, etc.) of the metal bond pad material (e.g., a layer of Cu. In some embodiments, a lithographic patterning process can follow the deposition of the metal bond pad material. A dielectric layer composed of a dielectric material such as, for example, silicon dioxide, can be located laterally adjacent to each of the metal bond pads that are present on each first semiconductor chip that provides the first semiconductor chip pairs X1-X2. In some embodiments, the dielectric layer is formed after the metal bond pads. In other embodiments, the dielectric layer is formed first, and thereafter the metal bond pads are formed into the dielectric layer utilizing a metallization process.

Referring now to FIG. 3, there is illustrated the exemplary structure shown in FIG. 2 after forming a first gap fill material 14 between each first semiconductor chip pair X1-X2. The first gap fill material 14 completely fills in the gap and is formed a sidewall of one of the first semiconductor chips, e.g., X1, of each first semiconductor chip pair X1-X2, and on a facing sidewall of another of the first semiconductor chips, e.g., X2, of each first semiconductor chip pair X1-X2. The first gap fill material 14 typically has a topmost surface that is coplanar with a topmost surface of the first semiconductor chips of each first semiconductor chip pair X1-X2. The bottommost surface of the first gap fill material 14 is coplanar with a bottommost surface of the first semiconductor chips of each first semiconductor chip pair X1-X2. The first gap fill material 14 can contact a surface of the bridge die 12.

In some embodiments, the first gap fill material 14 can be composed of an underfill material; the underfill material reinforces the position of each first semiconductor chip pair X1-X2. The underfill material employed is typically an epoxy containing fillers. In other embodiments, the first gap fill material 14 can be composed of a dielectric material such as, for example, silicon dioxide, silicon nitride or silicon oxynitride. In some embodiments and when an underfill material is employed as the first gap fill material 14, the underfill material is formed into the gap using any gap filling process. The structure is then heated to a temperature (such as, for example, 125° C. to 180° C.) to flow the underfill material. This temperature is held until the underfill material is cured. In some embodiments and when the dielectric material is employed as the first gap fill material 14, the dielectric material can be formed by a deposition process such as, for example, CVD, PECVD, ALD, or physical vapor deposition (PVD). In some embodiments, a planarization process such as, for example, CMP, can follow the coating or deposition process.

Referring now to FIG. 4, there is illustrated the exemplary structure shown in FIG. 3 after removing one of the first semiconductor chip pairs X1-X2 from the first fixture 10, placing the removed first semiconductor chip pair X1-X2 upside down in a second fixture 18, forming a plurality of second semiconductor chips including at least one second semiconductor pair Y1-Y2 on a surface of each first semiconductor chip pair, X1-X2, wherein each second semiconductor chip pair Y1-Y2 of the plurality of second semiconductor chips is connected to one of the bridge dies 12, and forming a second gap fill material 16 between each second semiconductor chip pair Y1-Y2. In some embodiments, the forming of the second gap fill material 16 can be omitted.

The first semiconductor chip pair X1-X2 can be removed from the first fixture 12 by hand or mechanical means and placed upside down in second fixture 18. In some embodiments, more than one first semiconductor chip pair X1-X2 can be removed from the first fixture 10 and placed in the second fixture 18. Second fixture 18 includes at least one recessed region that can house the removed first semiconductor chip pair X1-X2. The second fixture 18 includes materials as mentioned above for the first fixture 10. The at least one recessed region can be formed by techniques well known to those skilled in the art.

Next, a plurality of second semiconductor chips including at least one second semiconductor pair Y1-Y2 is formed on a surface of each first semiconductor chip pair, X1-X2 that is present in the second fixture 18. Each second semiconductor chip that provides the second semiconductor chip pairs Y1-Y2 has a second size and a second thickness. In one embodiment of the present application, the second size can be less than the first size, and the second thickness can be greater than the first thickness. In one example, the second size of each second semiconductor chips that provides the second semiconductor chip pairs Y1-Y2 is from 10 mm to 12 mm, and the second thickness for each second semiconductor chips that provides the second semiconductor chip pairs Y1-Y2 is from 100 μm to 785 μm.

Each second semiconductor chip that provides the second semiconductor chip pairs Y1-Y2 includes a FEOL as defined above, a MOL level as defined above, and a BEOL as defined above. Each second semiconductor chip that provides the second semiconductor chip pairs Y1-Y2 can also include backside power rails and a backside power distribution network located on a backside of the wafer. Each second semiconductor chip that provides the first semiconductor chip pairs Y1-Y2 that can be employed in the present application can be formed utilizing FEOL, MOL, BEOL, and backside wafer processing techniques that are well-known to those skilled in the art. Each second semiconductor chip that provides the second semiconductor chip pairs Y1-Y2 includes metal bond pads as defined above (not specifically shown).

In accordance with the present application, the forming of the second semiconductor pair Y1-Y2 on first semiconductor chip pair. X1-X2 includes aligning the metal bond pads that are present on the second semiconductor chip pair Y1-Y2 with the metal bond pads that are present on the first semiconductor chip pair X1-X2, intimately contacting the aligned metal bond pads of the first semiconductor chip pair X1-X2 and the second semiconductor chip pair Y1-Y2, and bonding the aligned and contacting metal bond pads of the first semiconductor chip pair X1-X2 and the second semiconductor chip pair Y1-Y2 together. Bonding is performed at a bonding temperature that causes metal bond pad to metal bond pad bonding. In one embodiment, the bonding temperature can for a Cu—Cu bond. In one example, the bonding temperature can be from 350° C. to 400° C. Bonding can be formed with the aid an external force or pressure on the contacted first semiconductor chip pair, X1-X2 and the second semiconductor chip pair Y1-Y2. As is illustrated in FIG. 4, the second semiconductor pair Y1-Y2 is bonded on first semiconductor chip pair, X1-X2 such that second semiconductor chip Y1 of the second semiconductor chip pair Y1-Y2 is bonded to first semiconductor chip X2 of the first semiconductor chip pair X1-X2, and second semiconductor chip Y2 of the second semiconductor chip pair Y1-Y2 is bonded to the first semiconductor chip X1 of the first semiconductor chip pair X1-X2. In the illustrated embodiment, and after the forming of the second semiconductor pair Y1-Y2 on first semiconductor chip pair, X1-X2, second gap fill material is formed.

The second gap fill material 16 completely fills in the gap that is present between the second semiconductor chips of the second semiconductor chip pair Y1-Y2. The second gap fill material 16 is formed a sidewall of one of the second semiconductor chips, e.g., Y1, of the second semiconductor chip pair Y1-Y2, and on a facing sidewall of another of the second semiconductor chip, e.g., YX2, of the second semiconductor chip pair Y1-Y2. The second gap fill material 16 is formed on top of and along the sidewalls of the bridge die 12. The second gap fill material 16 typically has a topmost surface that is coplanar with a topmost surface of the second semiconductor chips of the second semiconductor chip pair Y1-Y2. The bottommost surface of the second gap fill material 16 is coplanar with a bottommost surface of the second semiconductor chips of the second semiconductor chip pair Y1-Y2.

The second gap fill material 16 can be composed of one of the materials (i.e., underfill epoxies or dielectric material) mentioned above for the first gap fill material 14. The material that provides the second gap fill material 16 can be compositionally the same as, or compositionally different from, the material that provides the first gap fill material 14. The second gap fill material 16 can be formed utilizing one of the techniques mentioned above in forming the first gap fill material 14. In some embodiments, a planarization process such as, for example, CMP, or a mold back-grinding process can follow the coating or deposition process.

As shown in FIG. 4, a chip module assembly in accordance with the present application is provided. The chip module assembly, when subsequently flipped 180° from that shown in FIG. 4, includes the first semiconductor chip pair X1-X2 located at a first chip level, and the second semiconductor chip pair Y1-Y2 located on top of the first chip level (in the illustrated embodiment, the second semiconductor chip pair is located at a second chip level). In some embodiments, additional semiconductor chips can be stacked between the first and second semiconductor chip pairs illustrated in FIG. 4 utilizing the method described above.

As mentioned above, the second semiconductor pair Y1-Y2 is bonded on the first semiconductor chip pair, X1-X2 such that second semiconductor chip Y1 of the second semiconductor chip pair Y1-Y2 is bonded to first semiconductor chip X2 of the first semiconductor chip pair X1-X2, and second semiconductor chip Y2 of the second semiconductor chip pair Y1-Y2 is bonded to the first semiconductor chip X1 of the first semiconductor chip pair X1-X2. Bridge die 12 directly connects the first semiconductor chip pair X1-X2 together, and indirectly connects the second semiconductor chip pair Y1-Y2 together; bridge die 12 is spaced apart from each second semiconductor chip of the second semiconductor chip pair Y1-Y2. Notably, second semiconductor chip Y1 is connected to second semiconductor chip Y2 via the first semiconductor chip X2, the bridge die 12 and the second semiconductor chip X1. Note that a metal bond pad bonding interface (e.g., Cu—Cu bonding interface) exists between the first semiconductor chip pair X1-X2 and the second semiconductor chip pair Y1-Y2. This metal-to-metal bond pad interface, i.e., Cu—Cu bonded interface, enables very tight coupling between the first semiconductor chips and the second semiconductor chips, which provides very high bandwidth data transmission between the first semiconductor chips and the second semiconductor chips; further this data transmission comes at a very low energy cost (<<1 picoJoule/bit). The Cu—Cu bonds are in a dielectric material, and are therefore insulated from other Cu—Cu bonds.

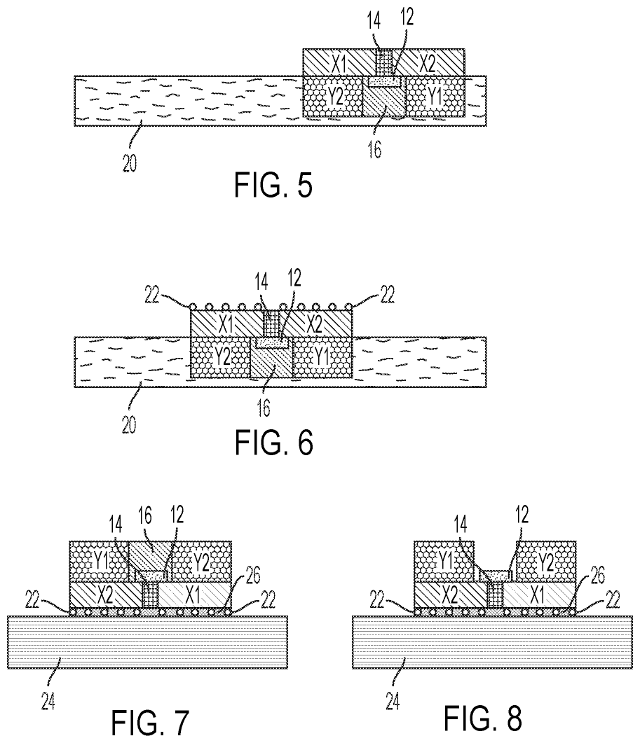

Referring now to FIG. 5, there is illustrated the exemplary structure of FIG. 4 after removing the chip module assembly from the second fixture 18 and placing the removed chip module assembly upside down in a third fixture 20. The chip module assembly can be removed from the second fixture 18 by hand or mechanical means and placed upside down in third fixture 20. In some embodiments, more than one chip module assembly can be removed from the second fixture 18 and placed in the third fixture 20. Third fixture 20 includes at least one recessed region that can house the removed chip module assembly. The third fixture 20 includes materials as mentioned above for the first fixture 10. The at least one recessed region can be formed by techniques well known to those skilled in the art.

Referring now to FIG. 6, there is illustrated the exemplary structure shown in FIG. 5 after forming a plurality of solder balls 22 on a physically exposed surface of the first semiconductor chip pair X1-X2 of the chip module assembly. Notably, the solder balls 22 are formed on metal bond pads (not shown) that are present on the physically exposed surface of the first semiconductor chip pair X1-X2 of the chip module assembly by a solder ball deposition technique. Each solder ball 22 is composed of a well-known solder material including, for example, a lead-free solder material. Although solder balls 22 are described and illustrated for the means of attachment, the present application contemplates embodiments in which other solder ball deposition means including, for example, injection molded solder can be used.

Referring now FIG. 7, there is illustrated the exemplary structure of FIG. 6 after bonding the chip module assembly to a laminate 24 to provide an electronic device in accordance with an embodiment of the present application. In some embodiments, underfill material (i.e., an epoxy material containing fillers) 26 is formed after bonding.

In some embodiments, the laminate 24 is double-sided, while in other embodiments laminate 24 is multilayered. The laminate 24 is composed of a material or stack of materials that are well-known to those skilled in semiconductor packaging. In one embodiment, the laminate 24 is a printed circuit board.

In the present application, bonding includes removing the chip module assembly containing solder balls 22 from the third fixture 20. The solder balls 22 on the removed chip module assembly are aligned with metal bond pads (not shown) on the laminate 24, and then the aligned chip module assembly and laminate 24 are brought into intimate contact with each other. An external force or pressure may be applied during the contacting and remain during the heating step. The contacted chip module assembly and laminate 24 are then heated to a bonding temperature to cause bonding between the solder balls 22 and the metal bond pads present on the laminate 24. In one example, the bonding temperature can be from 217° C. to 260° C.

The underfill material 26 is then in the gap between the two bonded structures utilizing any gap filling process. The bonded structures including the underfill material 26 are then heated to a temperature (for example, 125° C. to 180° C. to flow the underfill material. Capillary action then takes over to absorb the underfill under the chip. This temperature is held until the underfill is cured.

Referring now to FIG. 8, there illustrated another electronic device in accordance with another embodiment of the present application which can be derived from the processing illustrated in FIGS. 1-7. In the embodiment illustrate din FIG. 8, no second gap fill material 16 is used.

Notably, FIGS. 7 and 8 illustrate electronic devices in accordance with the present application. The illustrated electronic devices include a chip module assembly attached to laminate 24. The chip module assembly includes at least one first semiconductor chip pair X1-X2 located at a first chip level, a bridge die 12 interconnecting the at least one first semiconductor chip pair X1-X2, and at least one second semiconductor chip pair Y1-Y2 located on top of the first chip level, wherein the at least one second chip pair Y1-Y2 are connected to each other through the at least one first semiconductor chip pair X1-X2 and the bridge die 12.

In the embodiments mentioned above, the first semiconductor chips that provide the first semiconductor chip pair X1-X2 can be logic chips, while the second semiconductor chips that provide the second semiconductor chip pair can be memory chips. In some embodiments, the memory chips can be last level cache memory chips. In such embodiments, the logic chips have a direct access to the last level cache memory chips.

In the embodiments mentioned above, the first semiconductor chips that provide the first semiconductor chip pair X1-X2 can be logic chips, while the second semiconductor chips that provide the second semiconductor chip pair can also be logic chips.

In the embodiments mentioned above, the chip module assembly of the present application has inter-stack connectivity through the bridge chip 12.

In the embodiments mentioned above, the semiconductor die 12 can contain bridge memory, and the second semiconductor chip pair Y1-Y2 can gain access to this bridge memory with short semiconductor based paths. In such embodiments, the chip module assembly can be made using a scratchpad memory or other memory.

It is noted that although the present application describes embodiments in which the bridge die 12 is formed initially with the first semiconductor chip pair X1-X2, embodiments are contemplated in which the bridge die 12 is formed after placing the removed first semiconductor chip pair X1-X2 upside down in a second fixture 18, and before forming the plurality of second semiconductor chips including at least one second semiconductor pair Y1-Y2 on a surface of each first semiconductor chip pair, X1-X2. Also, and in other embodiments, the bridge die 12 can be formed after semiconductor chip stacking.

In any of the embodiments described above, at least one other semiconductor chip pair can be located between the first semiconductor chip pair X1-X2 and the second semiconductor chip pair Y1-Y2. In some embodiments, the at least one other semiconductor chip pair can have a same dimension and/or thickness as the first semiconductor chips that provide the first semiconductor chip pair X1-X2. In some embodiments, the at least one other semiconductor chip pair can include a bridge as described above connecting the semiconductor chips that provide the at least one other semiconductor chip pair. In other embodiments, the semiconductor chips that provide the at least one other semiconductor chip pair lack any bridge die.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An electronic device comprising:
a chip module assembly attached to a laminate, wherein the chip module assembly comprises at least one first semiconductor chip pair located at a first chip level, a bridge die interconnecting the at least one first semiconductor chip pair, and at least one second semiconductor chip pair located on top of the first chip level, wherein the at least one second chip pair are connected to each other through the at least one first semiconductor chip pair and the bridge die.

2. The electronic device of claim 1, wherein the at least one second semiconductor chip pair is located directly on top of the at least one first semiconductor chip pair.

3. The semiconductor structure of claim 2, wherein a metal bond pad bonding interface is present between the at least one second semiconductor chip pair and the at least one first semiconductor chip pair.

4. The electronic device of claim 3, wherein the metal bond pad bonding interface is a copper-copper interface.

5. The electronic device of claim 1, wherein the bridge die contains through silicon vias

6. The electronic device of claim 1, wherein at least one the first semiconductor chips of the first semiconductor chip pair contains through silicon vias.

7. The electronic device of claim 1, further comprising a first gap fill material located between each first semiconductor chip of the at least one first semiconductor chip pair.

8. The electronic device of claim 7, wherein the first gap fill material contacts a surface of the bridge die.

9. The electronic device of claim 7, further comprising a second gap fill material located between each second semiconductor chip of the at least one second semiconductor chip pair.

10. The electronic device of claim 9, wherein the second gap fill material is located on a topmost surface and a sidewall surface of the bridge die.

11. The electronic device of claim 1, wherein each first semiconductor chip of the at least one first semiconductor chip pair has a first dimension and a first thickness, and each second semiconductor chip of the at least one second semiconductor chip pair has a second dimension and a second thickness, wherein the first dimension is greater than the second dimension, and the first thickness is less than the second thickness.

12. The electronic device of claim 1, wherein the bridge die is spaced apart from each second semiconductor chip of the at least one second semiconductor chip pair by a gap.

13. The electronic device of claim 1, wherein the laminate is attached to the chip module assembly by solder balls.

14. The electronic device of claim 13, further comprising an underfill material located between the chip module assembly and the laminate.

15. The electronic device of claim 1, wherein the laminate is a printed circuit board.

16. The electronic device of claim 1, wherein the bridge chip is composed of a semiconductor material that contains wiring structures embedded therein.

17. The electronic device of claim 1, wherein each first semiconductor chip of the at least one first semiconductor chip pair is a logic chip, and each second semiconductor chip of the at least one second semiconductor chip pair is a memory chip.

18. The electronic device of claim 17, wherein the memory chip is a last level cache memory chip.

19. The electronic device of claim 1, wherein each first semiconductor chip of the at least one first semiconductor chip pair is a logic chip, and each second semiconductor chip of the at least one second semiconductor chip pair is another logic chip.

20. The electronic device of claim 1, wherein the bridge die contains memory.
